(19) United States
(12) Patent Application Publication
(10) Pub. No.: US 2025/0081443 A1
(43) Pub. Date: Mar. 6, 2025

(54) SEMICONDUCTOR DEVICE AND METHOD FOR FABRICATING THE SAME

(71) Applicant: SK hynix Inc., Gyeonggi-do (KR)

(72) Inventor: Min Chul SUNG, Gyeonggi-do (KR)

(21) Appl. No.: 18/439,768

(22) Filed: Feb. 13, 2024

(30) Foreign Application Priority Data
Aug. 29, 2023 (KR) 10-2023-0113524

(51) Int. Cl. H10B 12/00

(52) U.S. Cl. CPC H10B 12/482; H10B 12/02; H10B 12/315; H10B 12/34; H10B 12/485

(57) ABSTRACT

A method for fabricating a semiconductor device includes: forming an isolation layer that defines a plurality of active regions over a substrate; forming a bit line stack over the substrate; forming a main hard mask layer over the bit line stack; forming a plurality of first sacrificial mask layers over the main hard mask layer; forming a plurality of second sacrificial mask layers overlapping with both side ends of the first sacrificial mask layers over the first sacrificial mask layers; forming a main hard mask layer pattern by using the first and second sacrificial mask layers as barriers and etching the main hard mask layer; and forming a bit line structure by using the main hard mask layer pattern as a barrier and etching the bit line stack.

### CROSS-REFERENCE TO RELATED APPLICATIONS

The present application claims priority under 35 U.S.C 119 (a) to Korean Patent Application No. 10-2023-0113524, filed on Aug. 29, 2023, which is incorporated herein by reference in its entirety.

### BACKGROUND

### 1. Field

Various embodiments of the present invention relate to a semiconductor device, and more particularly, to a semiconductor device including a non-linear bit line, and a method for fabricating the semiconductor device.

### 2. Description of the Related Art

As semiconductor devices become more highly integrated, individual patterns are becoming finer and finer in order to position more elements of a semiconductor device in the same area. That is, as the degree of integration of semiconductor devices increases, design rules for the constituent elements of semiconductor devices are decreasing and issues such interference between neighboring elements become more difficult to resolve effectively. Hence, new innovative solutions are needed.

### SUMMARY

Embodiments of the present invention are directed to a semiconductor device that reduces interference between neighboring patterns, and to a method for fabricating the semiconductor device.

In accordance with an embodiment of the present invention, a method for fabricating a semiconductor device includes: forming an isolation layer that defines a plurality of active regions over a substrate; forming a bit line stack over the substrate; forming a main hard mask layer over the bit line stack; forming a plurality of first sacrificial mask layers over the main hard mask layer; forming a plurality of second sacrificial mask layers overlapping with both side ends of the first sacrificial mask layers over the first sacrificial mask layers; forming a main hard mask layer pattern by using the first and second sacrificial mask layers as barriers and etching the main hard mask layer; and forming a bit line structure by using the main hard mask layer pattern as a barrier and etching the bit line stack.

In accordance with another embodiment of the present invention, a semiconductor device includes: a substrate; an isolation layer formed over the substrate and defining a plurality of active regions; a bit line contact plug coupled to a portion of the active regions; and a bit line formed over the bit line contact plug, wherein the bit line includes: first line portions that intersect with the active regions; and second line portions that extend in a direction different from a direction of the first line portions and overlap with the isolation layer.

In accordance with another embodiment of the present invention, a semiconductor device includes: a plurality of active regions separated by an isolation layer; and a bit line stacked structure coupled to at least portions of the active regions; wherein the bit line stacked structure comprises a non-linear bit line which includes a plurality of alternating first and second line segments, and wherein the first and second line segments extend in a first and a second direction respectively.

### BRIEF DESCRIPTION OF THE DRAWINGS

FIG. 1A is a simplified plan view schematic illustrating a semiconductor device in accordance with an embodiment of the present invention.

FIG. 1B is a simplified cross-sectional view schematic taken along a line A-A′ shown in FIG. 1A.

FIG. 1C is a simplified cross-sectional view schematic taken along a line B-B′ shown in FIG. 1A.

FIGS. 2A to 12C are simplified schematics for illustrating a method for fabricating a semiconductor device in accordance with embodiments of the present invention.

FIGS. 13A to 13I are simplified schematics for illustrating a method for forming a main hard mask layer pattern.

FIG. 14 is a simplified schematic illustrating a semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

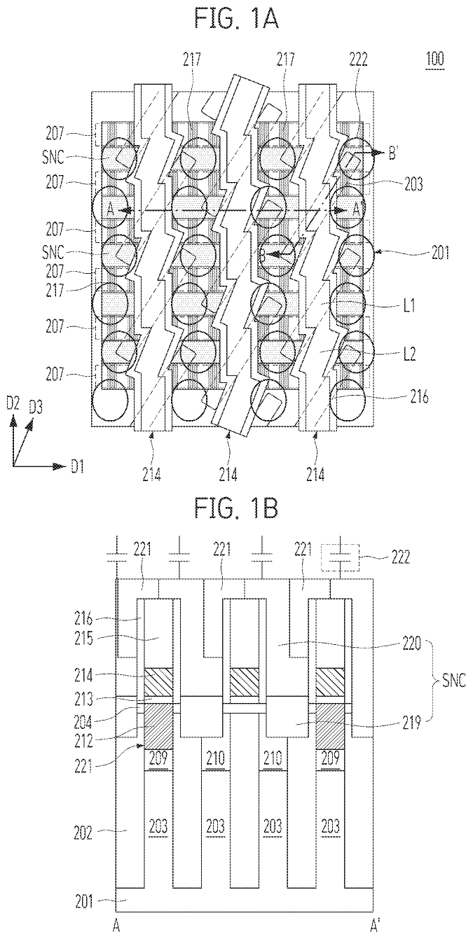

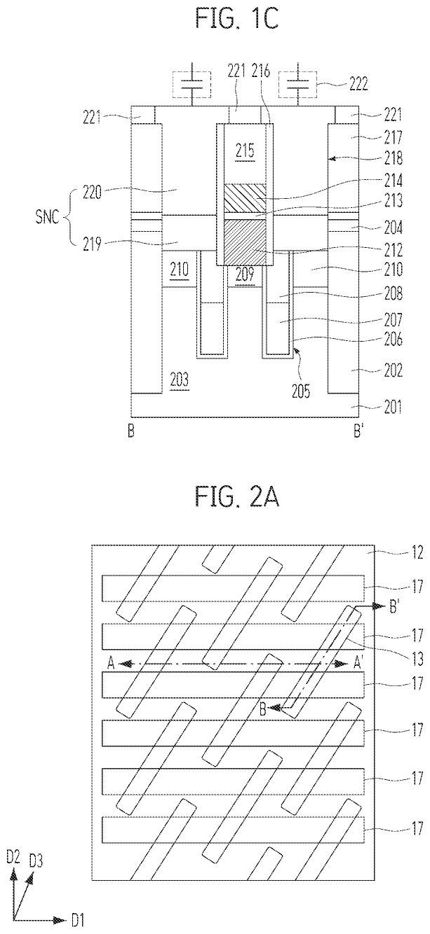

FIG. 1A is a simplified plan view schematic illustrating a semiconductor device in accordance with an embodiment of the present invention. FIG. 1B is a simplified cross-sectional view schematic taken along a line A-A′ shown in FIG. 1A. FIG. 1C is a simplified cross-sectional view schematic taken along a line B-B′ shown in FIG. 1A.

Referring to FIGS. 1A to 1C, the semiconductor device 100 may include a plurality of memory cells. Each memory cell may include a cell transistor including a buried word line 207, and a bit line 214.

Hereafter, the semiconductor device 100 will be described in detail.

An isolation layer 202 and an active region 203 may be formed over a substrate 201. A plurality of active regions 203 may be defined by the isolation layer 202. The substrate 201 may be a material suitable for semiconductor processing. The substrate 201 may include a semiconductor substrate. The substrate 201 may be formed of a material containing silicon. The substrate 201 may include silicon, monocrystalline silicon, polysilicon, amorphous silicon, silicon germanium, monocrystalline silicon germanium, polycrystalline silicon germanium, carbon doped silicon, a combination thereof, or multilayers thereof. The substrate 201 may also include other semiconductor materials, such as germanium. The substrate 201 may include a III/V-group semiconductor substrate, for example, a compound semiconductor substrate, such as GaAs. The substrate 201 may include a Silicon-On-Insulator (SOI) substrate. The isolation layer 202 may be formed by a Shallow Trench Isolation (STI) process.

A gate trench 205 may be formed in the substrate 201. A gate dielectric layer 206 may be formed conformally on the surface of the gate trench 205. A buried word line 207 may be formed over the gate dielectric layer 206 to partially fill the gate trench 205. More specifically, the buried word line 207 may fill a lower portion of the gate trench and leave the remaining dielectric layer 206 exposed. A gate capping layer 208 may be formed over the buried word line 207 and the remaining exposed gate dielectric layer 206 to fully fill any remaining space within the gate trench 205. The top surface of the buried word line 207 may be disposed at a lower level than the surface of the substrate 201. The buried word line 207 may be formed of a low-resistance metal material. For example, the buried word line 207 may be formed by sequentially stacking titanium nitride and tungsten. According to another embodiment of the present invention, the buried word line 207 may be formed of only titanium nitride (TiN Only). The buried word line 207 may also be referred to as a ‘buried gate electrode.’ The buried word line 207 may have a line shape from a top view and its long axis may extend along a first direction D1.

First and second impurity regions 209 and 210 may be formed in the substrate 201. The first and second impurity regions 209 and 210 may be spaced apart from each other by the gate trench 205. The first and second impurity regions may be formed on both sides of each gate trench 205. The first and second impurity regions 209 and 210 may also be referred to as source/drain regions. The first and second impurity regions 209 and 210 may include N-type impurities, such as arsenic (As) or phosphorus (P). The buried word line 207 together with the first and second impurity regions 209 and 210 may form a cell transistor. The cell transistor may exhibit an improved short channel effect because of the buried word line 207 structure.

A bit line contact plug 212 may be formed over the substrate 201. The bit line contact plug 212 may be coupled to the first impurity region 209. The bit line contact plug 212 may be disposed in a bit line contact hole 211. The bit line contact hole 211 may extend through a hard mask layer 204 toward the substrate 201. The hard mask layer 204 may be formed over the substrate 201. The hard mask layer 204 may include a dielectric material. The bit line contact hole 211 may expose the first impurity region 209. The lower surface of the bit line contact plug 212 may be lower than the top surfaces of the isolation layer 202 and the active regions 203. The bit line contact plug 212 may be formed of polysilicon. The bit line contact plug 212 may be formed of a metal material. A portion of the bit line contact plug 212 may have a line width which is smaller than the diameter of the bit line contact hole 211. A bit line barrier 213 may be formed over the top surface of the bit line contact plug 212, and the bit line 214 may be formed over the top surface of the bit line barrier 213. A bit line hard mask 215 may be formed over the top surface of the bit line 214.

The stacked structure of the bit line contact plug 212, the bit line barrier 213, the bit line 214, and the bit line hard mask 215 may also be referred to as a bit line structure. As it can be seen in FIG. 1A, the bit line 214 may have a non-linear line shape extending in a second direction D2 that intersects with the buried word line 207. A portion of the bit line 214 may be coupled to the bit line contact plug 212. The bit line 214 and the bit line contact plug 212 may have the same line width in the first direction D1. Accordingly, the bit line 214 may extend in the second direction D2 while covering the bit line contact plug 212. The bit line barrier 213 may include a metal nitride, such as titanium nitride. The bit line 214 may include a metal material, such as tungsten. The bit line hard mask 215 may include a dielectric material, such as silicon nitride.

A spacer structure 216 may be formed on the sidewall of the bit line structure. The spacer structure 216 may extend to be disposed on the sidewall of the bit line contact plug 212 but may only cover a portion of the bit line contact plug 212 leaving the remaining portion of the bit line contact plug 212 in direct contact with the isolation layer 202 as it can be seen in FIG. 1B. The spacer structure 216 may include silicon nitride, silicon oxide, a low-k material, or a combination thereof. The low-k material may include SiBN, SiCO, SiCN, SiBCN, or a combination thereof. For example, the spacer structure 216 may include an NKON, NKNAN, NKOK, NKOKN, NKAKN, KOK, or KAK multi-layer structure, where N refers to silicon nitride, and K refers to a low-k material, and O refers to silicon oxide, and A refers to an air gap. According to another embodiment of the present invention, the outermost spacer of the spacer structure 216 may include a low-k material.

A storage node contact plug SNC may be formed between pairs of neighboring bit line structures. The storage node contact plugs SNC may be coupled to the second impurity regions 210. The storage node contact plug SNC may include polysilicon, a metal nitride, a metal material, a metal silicide, or a combination thereof. According to an embodiment of the present invention, the storage node contact plug SNC may be formed by sequentially stacking polysilicon, cobalt silicide, and tungsten in the mentioned order.

From the perspective of a direction parallel to the bit line structure, a plug isolation layer 217 may be formed between the neighboring storage node contact plugs SNCs. The plug isolation layer 217 may be formed between the neighboring bit line structures. The neighboring storage node contact plugs SNC may be isolated in the second direction D2 by the plug isolation layers 217. Between the neighboring bit line structures, a plurality of plug isolation layers 217 and a plurality of storage node contact plugs SNC may be alternately disposed in the second direction D2. The storage node contact plug SNC may include a stack of a lower plug 219 and an upper plug 220. The storage node contact plug SNC may be formed in a storage node contact hole 218. The storage node contact hole 218 may be formed between the plug isolation layers 217 and the bit line structure. Plug capping layers 221 may be formed between the neighboring upper plugs 220. The plug capping layers 221 may include silicon oxide, silicon nitride, silicon carbon oxide, or a combination thereof.

A memory element 222 may be formed over the storage node contact plug SNC. The memory element 222 may include a capacitor containing a storage node. The storage node may be a pillar type. Although not illustrated, a dielectric layer and a plate node may be further formed over the storage node. In a variation of this embodiment, the storage node may have a cylindrical shape instead of a pillar shape.

The plug isolation layer 217 may include silicon nitride or a low-k material. When the plug isolation layer 217 includes a low-k material, parasitic capacitance between the neighboring storage node contact plugs SNCs with the plug isolation layer 217 between them may be reduced. The plug isolation layer 217 may include SiCO, SiCN, SiOCN, SiBN, or SiBCN.

According to FIGS. 1A to 1C, the bit line 214 may have a non-linear structure. From the perspective of a top view, the bit line 214 may have a hybrid line shape in which a plurality of first line portions L1 and a plurality of second line portions L2 are merged in an alternating pattern. As shown in FIG. 1A, the plurality of the first line portions L1 may each be aligned along the second direction D2 while the plurality of the second line portions L2 may be parallel to each other and oriented in a third direction D3 forming an acute angle with the second direction D2. Just like the bit line 214, the bit line hard mask 215 may also have a non-linear structure, that is, a hybrid line shape.

The first line portions L1 and the second line portions L2 may have different directions. For example, the first line portions L1 may extend in the second direction D2, and the second line portions L2 may extend in a third direction D3. Here, the third direction D3 may be the same as the direction of the active region 13.

The first line portions L1 may vertically overlap with the bit line contact plugs 212, and the second line portions L2 may vertically overlap with the isolation layer 202. Each of the first and second line portions L1 and L2 may have an island shape, a bar shape, or a small line shape. The first line portions L1 and the second line portions L2 may be coupled to each other in an alternating pattern. The first line portions L1 may extend in a direction that intersects with the active regions 203, and the second line portions L2 may vertically overlap with the isolation layer 202. The second line portions L2 may not overlap with the active regions 203. The second line portions L2 and the active regions 203 may extend in the third direction D3. The second line portions L2 and the active regions 203 may have non-overlapping directions.

Both sidewalls of the bit line 214 may have non-linearity according to the direction that the bit line 214 extends. The first line portions L1 and the second line portions L2 may be alternately arranged in the direction that the bit line 214 extends.

From the perspective of the B-B′ direction shown in FIG. 1A, two storage node contact plugs SNCs and one bit line 214 may be coupled to one active region 203. In this case, the second line portions L2 of the bit line 214 may be adjacent to the storage node contact plugs SNC in the first direction D1. The storage node contact plugs SNC may be coupled to the edges of each of the active regions 203, and the bit line 214 may be coupled to the center of each of the active regions 203 through the bit line contact plug 212.

As described above, since the bit line 214 has a non-linear structure including the first line portions L1 and the second line portions L2, the interference between the storage node contact plug SNC and the bit line 214 may be minimized. Since the second line portions L2 of the bit line 214 do not overlap with the active regions 203, it is possible to secure the space sufficient to form the storage node contact plug SNC.

As a comparative example, when the second line portions L2 extend in the second direction D2 in the same manner that the first line portions L1 extend, the active regions 203 and the second line portions L2 may overlap. Therefore, the space where the storage node contact plug SNC is formed may become narrow. Accordingly, the resistance of the storage node contact plug SNC may increase.

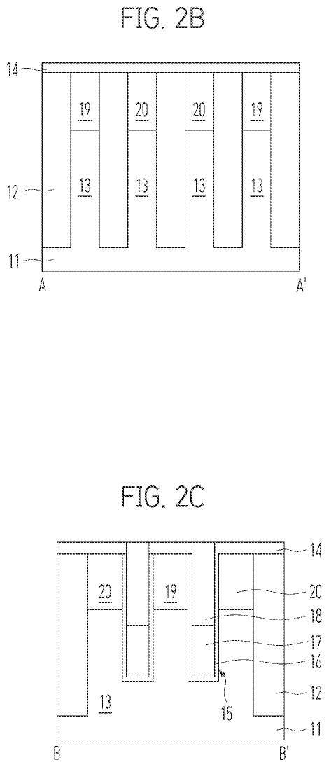

FIGS. 2A to 12C illustrate a method for fabricating a semiconductor device in accordance with embodiments of the present invention. FIGS. 2B to 12B illustrate a fabrication method taken along a line A-A′ shown in FIGS. 2A to 12A. FIGS. 2C to 12C illustrate a fabrication method taken along a line B-B′ shown in FIGS. 2A to 12A.

Referring to FIGS. 2A to 2C, an isolation layer 12 may be formed over a substrate 11. A plurality of active regions 13 may be defined by the isolation layer 12. The isolation layer 12 may be formed by a Shallow Trench Isolation (STI) process. The STI process may include etching the substrate 11 to form an isolation trench (whose reference numeral is omitted), and, then, filling the isolation trench with a dielectric material to form the isolation layer 12. The isolation layer 12 may include silicon oxide, silicon nitride, or a combination thereof. A Chemical Vapor Deposition (CVD) process or other deposition processes may be performed to fill the isolation trench with a dielectric material. A planarization process, such as Chemical-Mechanical Polishing (CMP), may be additionally performed.

Subsequently, a buried word line structure may be formed in the substrate 11. The buried word line structure may include a gate trench 15, a gate dielectric layer 16 conformally covering the bottom and sidewalls of the gate trench 15, a buried word line 17 filling a portion of the gate trench 15 over the gate dielectric layer 16, and a gate capping layer 18 formed over the buried word line 17.

A method of forming the buried word line structure may be performed as follows: First, a gate trench 15 may be formed in the substrate 11. The gate trench 15 may have a line shape crossing the active regions 13 and the isolation layer 12. The gate trench 15 may be formed by forming a mask pattern (not shown) over the substrate 11 and performing an etching process using the mask pattern as an etch mask. To form the gate wrench 15, a hard mask layer 14 may be used as an etch barrier. The hard mask layer 14 may have a shape patterned by the mask pattern. The hard mask layer 14 may include silicon oxide. The hard mask layer 14 may include Tetra Ethyl Ortho Silicate (TEOS). The bottom surface of the gate trench 15 may be disposed at a higher level than the bottom surface of the isolation layer 12.

Although not illustrated, a portion of the isolation layer 12 may be recessed to protrude the active region 13 below the gate trench 15. For example, the isolation layer 12 below the gate trench 15 may be selectively recessed in the longitudinal direction of the gate trench 15. As a result, a fin region (whose reference numeral is omitted) may be formed below the gate trench 15. The fin region may be portion of a channel region.

Subsequently, a gate dielectric layer 16 may be formed on the bottom and sidewalls of the gate trench 15. Before the gate dielectric layer 16 is formed, the etch damage on the surface of the gate trench 15 may be recovered. For example, after a sacrificial oxide is formed through a thermal oxidation process, the sacrificial oxide may be removed.

The gate dielectric layer 16 may be formed by a thermal oxidation process. For example, the gate dielectric layer 16 may be formed by oxidizing the bottom and sidewalls of the gate trench 15.

According to another embodiment of the present invention, the gate dielectric layer 16 may be formed by a deposition method, such as Chemical Vapor Deposition (CVD) or atomic layer deposition (ALD). The gate dielectric layer 16 may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, and a combination thereof.

According to another embodiment of the present invention, the gate dielectric layer 16 may be formed by depositing a liner polysilicon layer and then radically oxidizing the liner polysilicon layer.

According to another embodiment of the present invention, the gate dielectric layer 16 may be formed by forming a liner silicon nitride layer and then radically oxidizing the liner silicon nitride layer.

Subsequently, a buried word line 17 may be formed over the gate dielectric layer 16. To form the buried word line 17, a conductive layer (not shown) may be formed to fill the gate trench 15, and then a recessing process may be performed. The recessing process may be performed by performing an etch-back process, or by performing a Chemical Mechanical Polishing (CMP) process and performing an etch-back process sequentially. The buried word line 17 may have a recessed shape that fills portion of the gate trench 15. The top surface of the buried word line 17 may be disposed at a lower level than the top surface of the active region 13. The buried word line 17 may include a metal, a metal nitride, or a combination thereof.

For example, the buried word line 17 may be formed of titanium nitride (TiN), tungsten (W), or a stack (TiN/W) of titanium nitride/tungsten. The titanium nitride/tungsten (TiN/W) stack may be a structure in which titanium nitride is conformally formed and then the gate trench 15 is partially filled with tungsten. Titanium nitride may be used alone as the buried word line 17, and may also be referred to as a buried word line 17 of a ‘TIN Only’ structure. As the buried word line 17, a double gate structure of a titanium nitride/tungsten (TiN/W) stack and a polysilicon layer may be used.

Subsequently, a gate capping layer 18 may be formed over the buried word line 17. The gate capping layer 18 may include a dielectric material. The remaining portion of the gate trench 15 over the buried word line 17 may be filled with the gate capping layer 18. The gate capping layer 18 may include silicon nitride. According to another embodiment of the present invention, the gate capping layer 18 may include silicon oxide. According to yet another embodiment of the present invention, the gate capping layer 18 may have a Nitride-Oxide-Nitride (NON) structure. The top surface of the gate capping layer 18 may be disposed at the same level as the top surface of the hard mask layer 14. To this end, a Chemical Mechanical Polishing (CMP) process may be performed while the gate capping layer 18 is formed.

After the gate capping layer 18 is formed, impurity regions 19 and 20 may be formed. The impurity regions 19 and 20 may be formed through a doping process, such as implantation. The impurity regions 19 and 20 may include a first impurity region 19 and a second impurity region 20. The first and second impurity regions 19 and 20 may be doped with impurities of the same conductivity type. The first and second impurity regions 19 and 20 may have the same depth. According to another embodiment of the present invention, the first impurity region 19 may be deeper than the second impurity region 20. The first and second impurity regions 19 and 20 may also be referred to as source/drain regions. The first impurity region 19 may be an region to which a bit line contact plug is to be coupled, and the second impurity region 20 may be an region to which a storage node contact plug is to be coupled. The first impurity region 19 and the second impurity region 20 may be disposed in different active regions 13. Also, the first impurity region 19 and the second impurity region 20 may be disposed in the active regions 13, respectively, spaced apart from each other by the gate trenches 15. For example, the first impurity region 19 may be formed between two adjacent gate trenches 15. The second impurity region 20 may be formed between gate trench 15 and the isolation layer 12

A cell transistor of a memory cell may be formed by the buried word line 17 and the first and second impurity regions 19 and 20.

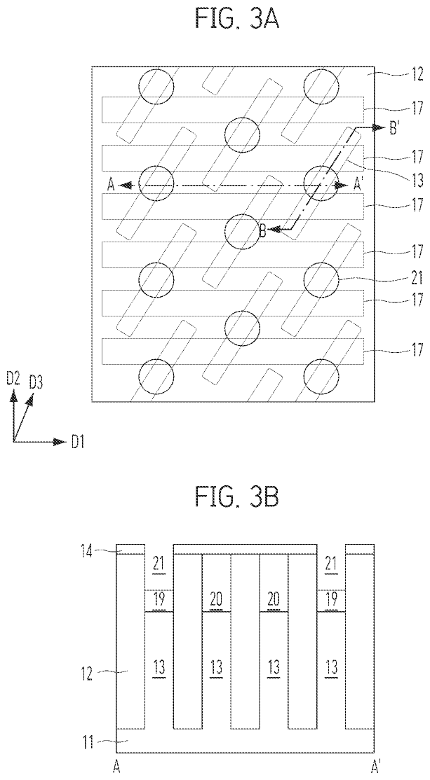

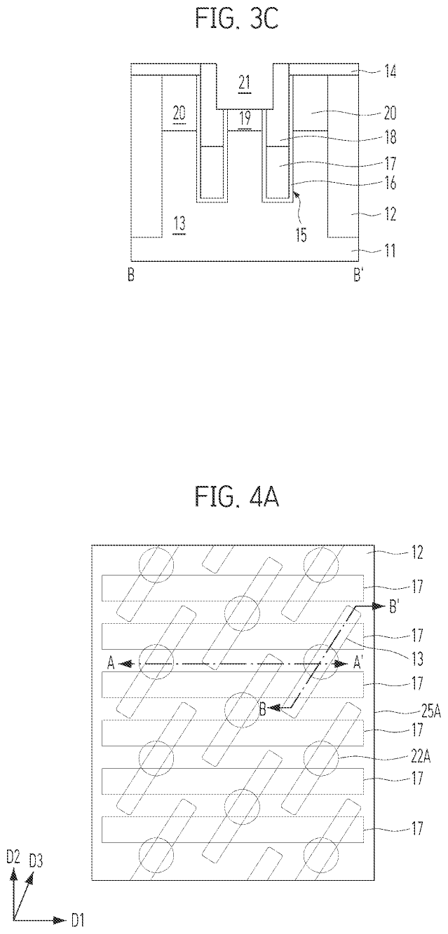

Referring to FIGS. 3A to 3C, a bit line contact hole 21 may be formed. To form the bit line contact hole 21, the hard mask layer 14 may be etched by using a contact mask (not shown). The bit line contact hole 21 may have a circular shape or an elliptical shape from the perspective of a simplified plan view schematic. A portion of the substrate 11 may be exposed by the bit line contact hole 21. The bit line contact hole 21 may have a diameter that is controlled to a predetermined line width. The bit line contact hole 21 may be shaped to expose a portion of the active region 13. For example, the first impurity region 19 may be exposed by the bit line contact hole 21. The bit line contact hole 21 may have a diameter that is greater than the width of the minor axis of the active region 13. Accordingly, in the etching process for forming the bit line contact hole 21, the first impurity region 19, the isolation layer 12, and a portion of the gate capping layer 18 may be etched. The gate capping layer 18, the first impurity region 19, and the isolation layer 12 below the bit line contact hole 21 may be recessed to a predetermined depth.

Accordingly, the bottom surface of the bit line contact hole 21 may expand into the substrate 11. As the bit line contact hole 21 expands, the surface of the first impurity region 19 may be recessed, and the surface of the first impurity region 19 may be disposed at a lower level than the surface of the active region 13.

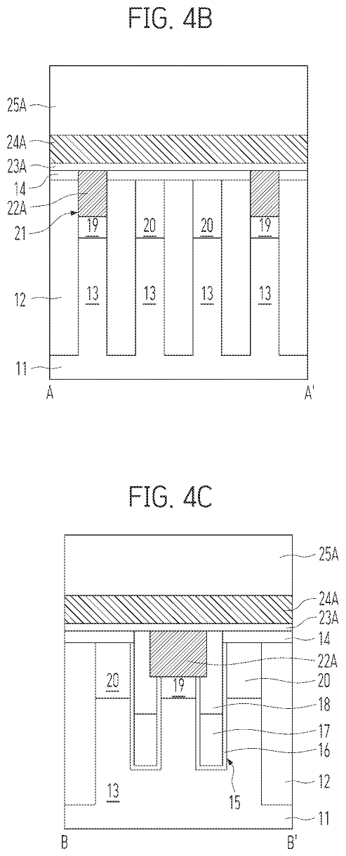

Referring to FIGS. 4A to 4C, a preliminary plug 22A may be formed in the bit line contact hole 21. The preliminary plug 22A may be formed by a selective epitaxial growth (SEG) process. For example, the preliminary plug 22A may include a phosphorus-doped epitaxial layer, e.g., SEG SiP. Using the selective epitaxial growth process for forming the preliminary plug 22A is advantageous because the preliminary plug is formed without voids. According to another embodiment of the present invention, the preliminary plug 22A may be formed by depositing a polysilicon layer and performing a CMP process. The preliminary plug 22A may fill the bit line contact hole 21. The top surface of the preliminary plug 22A may be disposed at the same level as the top surface of the hard mask layer 14.

Subsequently, a bit line barrier layer 23A, a bit line conductive layer 24A, and a bit line hard mask layer 25A may be stacked over the preliminary plug 22A and the hard mask layer 14 sequentially in the recited order. The bit line barrier layer 23A and the bit line conductive layer 24A may include a metal-containing material. The bit line barrier layer 23A and the bit line conductive layer 24A may include a metal, a metal nitride, a metal silicide, or a combination thereof. According to an embodiment of the present invention, the bit line barrier layer 23A may include titanium nitride, and the bit line conductive layer 24A may include tungsten (W). The bit line hard mask layer 25A may be formed of a dielectric material having an etch selectivity with respect to the bit line conductive layer 24A and the preliminary plug 22A. The bit line hard mask layer 25A may include silicon oxide or silicon nitride. According to an embodiment of the present invention, the bit line hard mask layer 25A may be formed of silicon nitride.

A stack of the preliminary plug 22A, the bit line barrier layer 23A, the bit line conductive layer 24A, and the bit line hard mask layer 25A may also be referred to as a ‘bit line stack’.

Subsequently, a double patterning process may be performed to form a bit line structure.

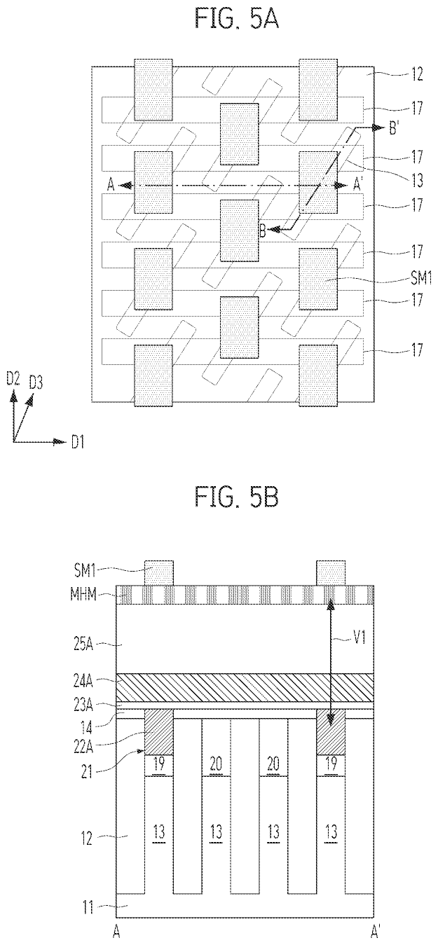

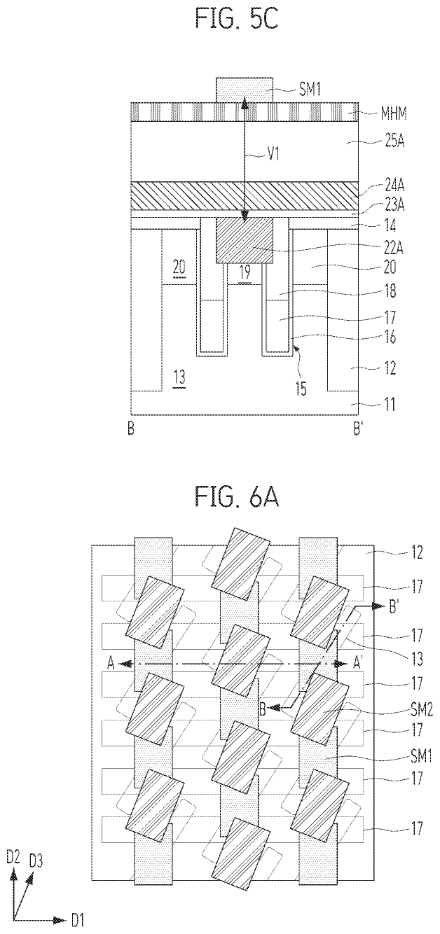

Referring to FIGS. 5A to 5C, a main hard mask layer MHM may be formed over the bit line hard mask layer 25A of the bit line stack. The main hard mask layer MHM may include a material having an etch selectivity with respect to the bit line barrier layer 23A, the bit line conductive layer 24A, and the bit line hard mask layer 25A. For example, the main hard mask layer MHM may include a carbon-containing material, formed, for example, by a spin-on-coating process.

A plurality of first sacrificial mask layers SM1 may be formed over the main hard mask layer MHM. The main hard mask layer MHM and the first sacrificial mask layers SM1 may be formed of different materials. The first sacrificial mask layers SM1 may include silicon oxide. From the perspective of a top view, the first sacrificial mask layers SM1 and the bit line contact holes 21 may vertically overlap with each other as denoted by the arrow ‘V1’, and the first sacrificial mask layers SM1 and the preliminary plugs 22A may also vertically overlap with each other also as denoted by arrow ‘V1’. The first sacrificial mask layers SM1 may have an island shape, a bar shape, or a small line shape.

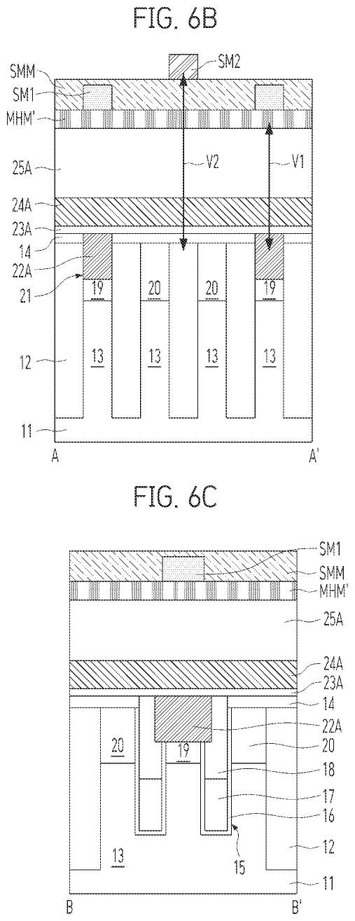

Referring to FIGS. 6A to 6C, a middle sacrificial mask layer SMM may be formed over the first sacrificial mask layers SM1. The middle sacrificial mask layer SMM and the first sacrificial mask layers SM1 may be formed of different materials. The middle sacrificial mask layer SMM and the main hard mask layer MHM may be formed of the same material. The middle sacrificial mask layer SMM may include a carbon-containing material, formed, for example, by a spin-on-coating process.

A plurality of second sacrificial mask layers SM2 may be formed over the middle sacrificial mask layer SMM. The second sacrificial mask layers SM2 and the middle sacrificial mask layer SMM may be formed of different materials. The first sacrificial mask layers SM1 and the second sacrificial mask layers SM2 may be formed of the same material. The second sacrificial mask layers SM2 and the main hard mask layer MHM may be formed of different materials. The second sacrificial mask layers SM2 may include silicon oxide. From the perspective of a top view, the second sacrificial mask layers SM2 and the isolation layers 12 may vertically overlap with each other as denoted by arrow ‘V2’. From the perspective of a top view, both side ends of the second sacrificial mask layers SM2 and both side ends of the first sacrificial mask layers SM1 may vertically overlap with each other (See FIG. 6A). The second sacrificial mask layers SM2 may have an island shape, a bar shape, or a small line shape.

The first sacrificial mask layers SM1 and the second sacrificial mask layers SM2 may have different directions. For example, the first sacrificial mask layers SM1 may extend in the second direction D2, and the second sacrificial mask layers SM2 may extend in the third direction D3. Here, the third direction D3 may be the same as the direction of the active regions 13.

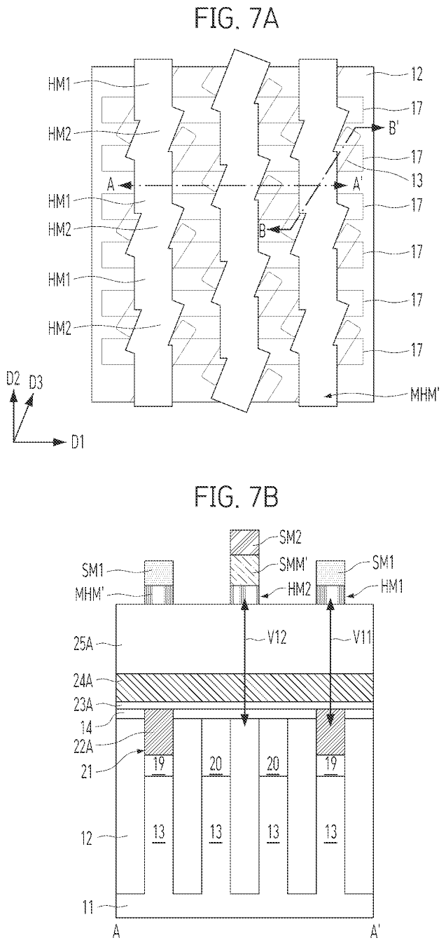

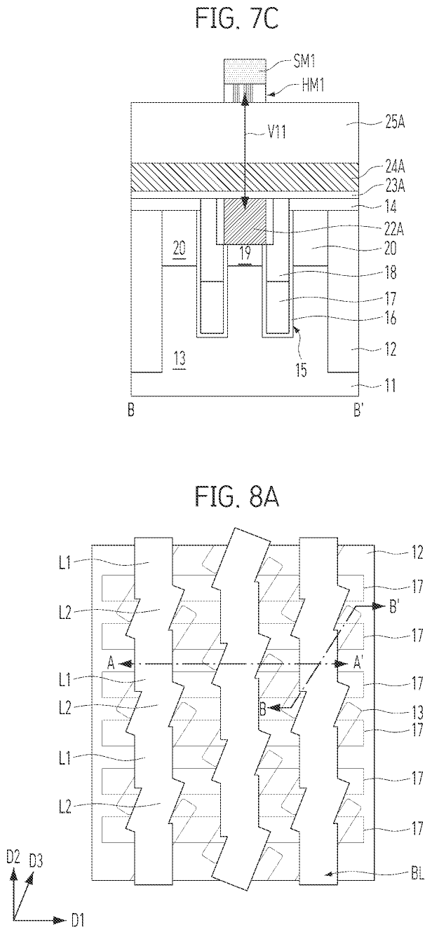

Referring to FIGS. 7A to 7C, main hard mask layer patterns MHM′ may be formed by using the first sacrificial mask layers SM1 and the second sacrificial mask layers SM2. The process of forming the main hard mask layer patterns MHM′ may include forming the middle sacrificial mask layer patterns SMM′ by using the second sacrificial mask layers SM2 as barriers and etching the middle sacrificial mask layer SMM and forming the main hard mask layer patterns MHM′ by using the first sacrificial mask layers SM1, the middle sacrificial mask layer patterns SMM′, and the second sacrificial mask layers SM2 as barriers and etching the main hard mask layer MHM.

From the perspective of a top view, each main hard mask layer pattern MHM′ may have a shape in which the shapes of the first sacrificial mask layers SM1 and the shapes of the second sacrificial mask layers SM2 are merged. Each main hard mask layer pattern MHM′ may include first and second portions HM1 and HM2 coupled in an alternating pattern. The first portions HM1 correspond to the shape of the first sacrificial mask layers SM1. The second portions HM2 correspond to the shape of the second sacrificial mask layers SM2. The first portions HM1 of the individual main hard mask layer patterns MHM′ may vertically overlap with the bit line contact holes 21 as denoted by arrow ‘V11’. The first portions HM1 of the individual main hard mask layer patterns MHM′ and the preliminary plugs 22A may also vertically overlap with each other (also denoted by arrow ‘V11’).

The second portions HM2 of the individual main hard mask layer patterns MHM′ may vertically overlap with the isolation layers 12 as denoted with arrow ‘V12’.

The first portions HM1 and the second portions HM2 of the individual main hard mask layer patterns MHM′ may be coupled to each other to form a continuous strip with non-linear polygonal sides comprising liner segments of different orientation.

As described above, each main hard mask layer pattern MHM′ may have a hybrid line shape in which a plurality of first portions HM1 and a plurality of second portions HM2 are merged.

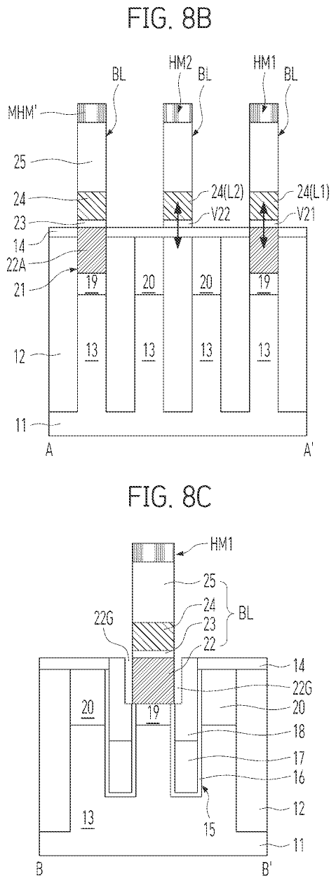

Referring to FIGS. 8A to 8C, a plurality of bit line structures BL may be formed by performing a bit line patterning process. The process of forming the individual bit line structure BL may include etching the bit line stack by using the main hard mask layer patterns MHM′ as barriers and etching the preliminary plug 22A by using the main hard mask layer patterns MHM′ as barriers. The process of etching the bit line stack may include sequentially etching the bit line hard mask layer 25A, the bit line conductive layer 24A, and the bit line barrier layer 23A by using the main hard mask layer patterns MHM′ as barriers. During the bit line patterning process using the individual main hard mask layer patterns MHM′ as barriers, the middle sacrificial mask layer patterns SMM′, the first sacrificial mask layers SM1, and the second sacrificial mask layers SM2 may be removed.

Each bit line structure BL may include a stack of a bit line contact plug 22, a bit line barrier 23, a bit line 24, and a bit line hard mask 25. The bit line hard mask 25 may be formed by etching the bit line hard mask layer 25A, and the bit line 24 may be formed by etching the bit line conductive layer 24A. The bit line barrier 23 may be formed by etching the bit line barrier layer 23A, and the bit line contact plug 22 may be formed by etching the preliminary plug 22A. The preliminary plug 22A may be formed to have the same line width as the line width of the bit line 24. The bit line contact plug 22 may be formed over the first impurity region 19. The bit line contact plug 22 may couple the first impurity region 19 and the bit line 24 to each other. The bit line contact plug 22 may be formed in the bit line contact hole 21. The line width of the bit line contact plug 22 may be smaller than the diameter of the bit line contact hole 21. Accordingly, gaps 22G may be defined on both sides of the bit line contact plug 22.

As described above, as the bit line contact plug 22 is formed, a gap 22G may be formed in the bit line contact hole 21. This is because the bit line contact plug 22 is formed by being etched to be smaller than the diameter of the bit line contact hole 21. The gap 22G may be formed independently on both sidewalls of the bit line contact plug 22 without having a surrounding shape that surrounds the bit line contact plug 22. One bit line contact plug 22 and a pair of gaps 22G may be disposed in the bit line contact hole 21, and the pair of gaps 22G may be separated by the bit line contact plug 22. The bottom surface of the gap 22G may extend into the inside of the gate capping layer 18. The bottom surface of the gaps 22G may be disposed at a lower level than the recessed top surface of the first impurity region 19.

From the perspective of a top view, each of the bit line structures BL may have a hybrid line shape in which a plurality of first line portions L1 and a plurality of second line portions L2 are merged.

The first line portions L1 and the second line portions L2 may have different directions. For example, the first line portions L1 may extend in the second direction D2, and the second line portions L2 may extend in the third direction D3. Here, the third direction D3 may be the same as the direction of the active region 13.

The first line portions L1 may correspond to the first portions HM1 of the individual main hard mask layer patterns MHM′, and the second line portions L2 may correspond to the second portions HM2 of the individual main hard mask layer patterns MHM′. The first line portions L1 may vertically overlap with the bit line contact plugs 22 (see arrow ‘V21’), and the second line portions L2 may vertically overlap with the isolation layer 12 (see arrow ‘V22’). Each of the first and second line portions L1 and L2 may have an island shape, a bar shape, or a small line shape. The first line portions L1 and the second line portions L2 may be coupled to each other.

The first line portions L1 may extend in a direction that intersects with the active regions 13, and the second line portions L2 may vertically overlap with the isolation layer 12.

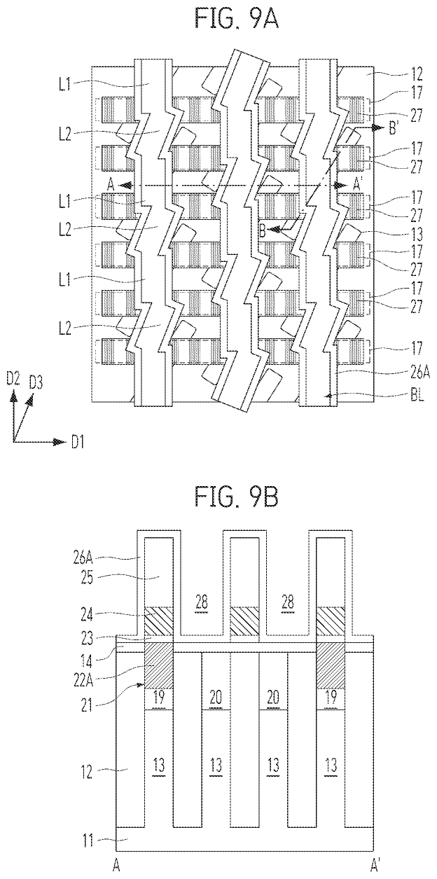

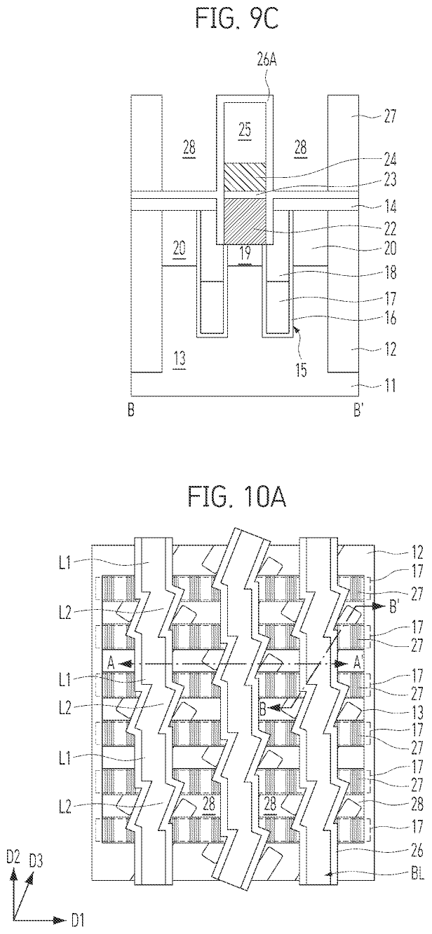

Referring to FIGS. 9A to 9C, after the main hard mask layer patterns MHM′ are removed, a spacer layer 26A may be formed over the bit line structures BL. The spacer layer 26A may cover both sidewalls and the top surface of the bit line structures BL. The spacer layer 26A may extend to be disposed on both sidewalls of the bit line contact plugs 22. The spacer layer 26A may include a dielectric material. The spacer layer 26A may include silicon oxide, silicon nitride, silicon carbon oxide, or a combination thereof. The spacer layer 26A may be a multi-layer spacer, such as NON (Nitride-Oxide-Nitride). The spacer layer 26A may include materials having different dielectric constants.

Subsequently, plug isolation layers 27 may be formed. The plug isolation layers 27 may include silicon nitride. The plug isolation layers 27 may be disposed between the bit line structures BL. The plug isolation layer 27 may be formed by depositing silicon nitride and performing an etching process sequentially.

The storage node contact hole 28 may be defined by the plug isolation layers 27.

Since the bit line structure BL, particularly, the second line portions L2 of the bit line 24, does not overlap with the active regions 13, the open area of the storage node contact hole 28 may be secured sufficiently. Accordingly, it is possible to prevent a not-open phenomenon of the storage node contact hole 28.

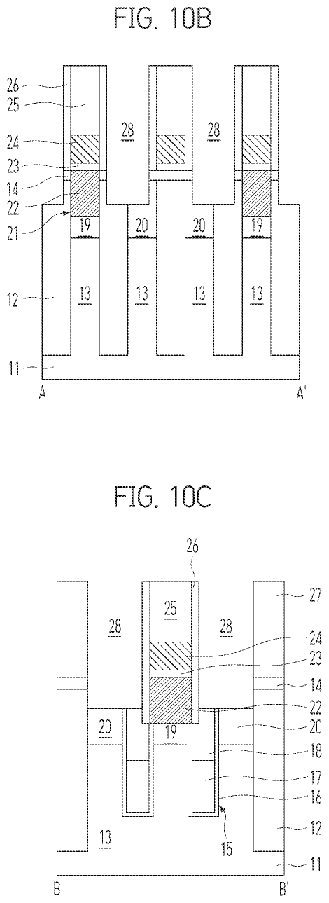

Referring to FIGS. 10A to 10C, the spacer layer 26A may be etched to form the spacer 26. Subsequently, the underlying materials may be etched to be self-aligned to the spacer 26. As a result, the storage node contact hole 28 may extend between the bit line structures. The storage node contact hole 28 may expose a portion of the active region 13.

Referring to FIGS. 11A to 11C, a storage node contact plug SNC may be formed. The storage node contact plug SNC may include a stack of a lower plug 29 and an upper plug 30. The lower plug 29 may include polysilicon or monocrystalline silicon. The upper plug 30 may include a metal material. The lower plug 29 may fill the lower region of the storage node contact hole 28, and the upper plug 30 may cover the upper region of the storage node contact hole 28 and may extend to also cover at least partially the top surface of the bit line structure BL.

As described above, since the bit line 24 has a non-linear structure including the first line portions L1 and the second line portions L2, interference between the storage node contact plug SNC and the bit line 24 may be reduced significantly or fully eliminated. Since the second line portions L2 of the bit line 24 do not overlap with the active regions 13, the space where the storage node contact plug SNC is to be formed may be secured sufficiently. Accordingly, an increase in the resistance of the storage node contact plug SNC may be suppressed.

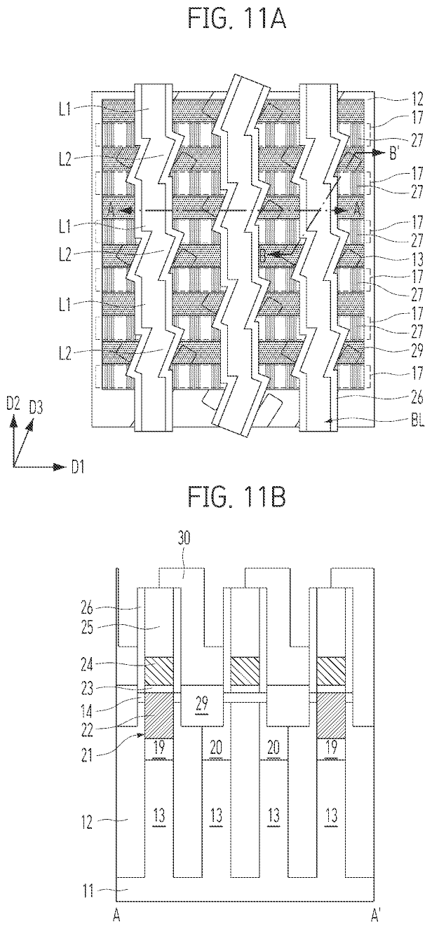

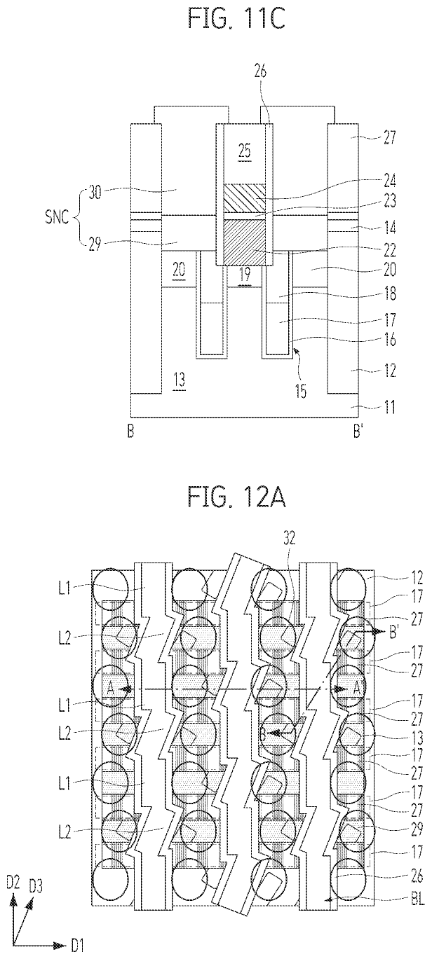

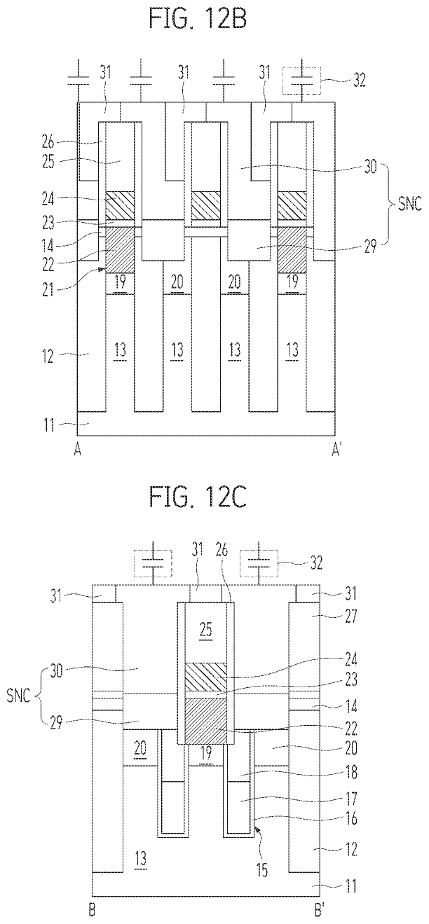

Referring to FIGS. 12A to 12C, a plug capping layer 31 may be formed over the storage node contact plug SNC. The plug capping layer 31 may fill between the upper plugs 30.

A capacitor 32 may be formed over the plug capping layer 31 and the storage node contact plug SNC. The capacitor 32 may include a lower electrode, a dielectric layer, and an upper electrode, and the lower electrode may have a cylindrical shape or a pillar shape.

According to the embodiment of the present invention described above, the open area of the storage node contact hole 28 may be maximized by minimizing the interference between the storage node contact plug SNC and the bit line 24, and through this, it is possible to suppress the occurrence of not-open defects that may be caused by line width scaling and defects originating from the increased resistance.

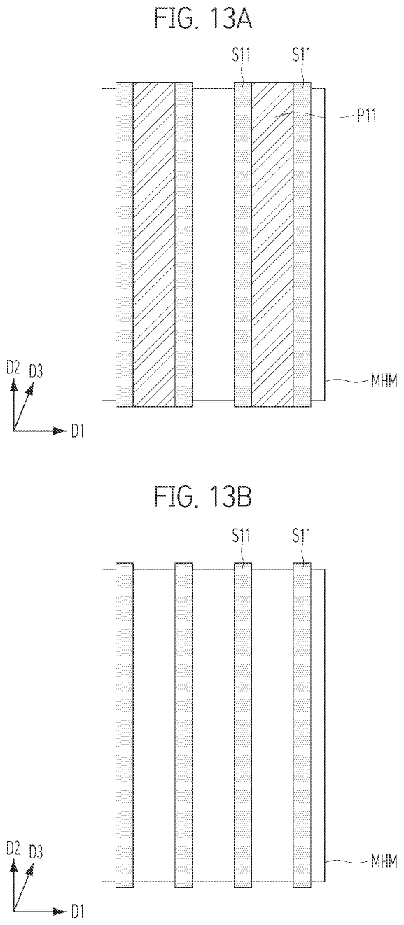

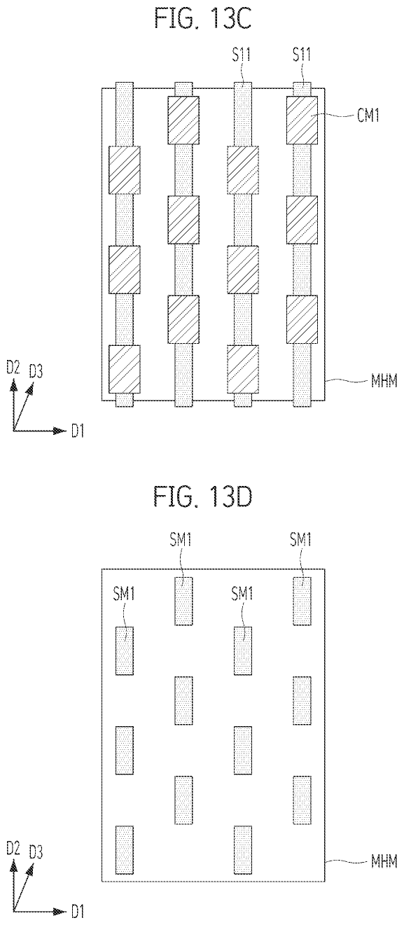

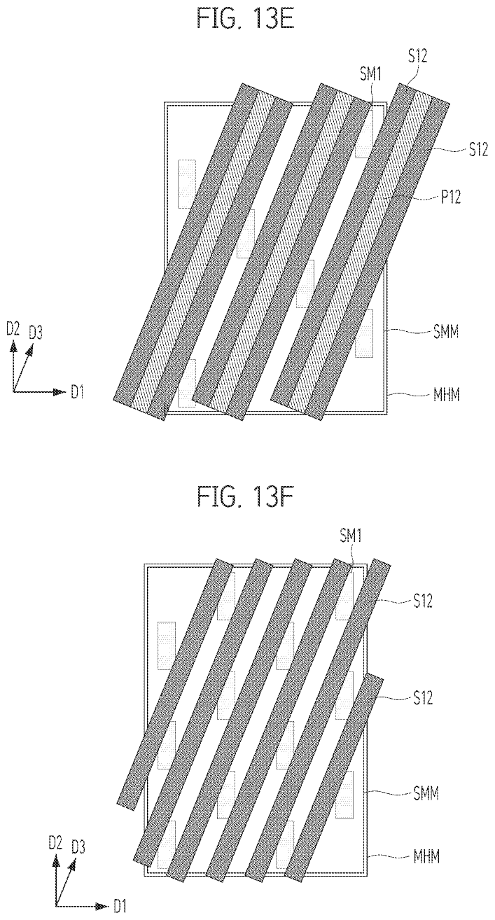

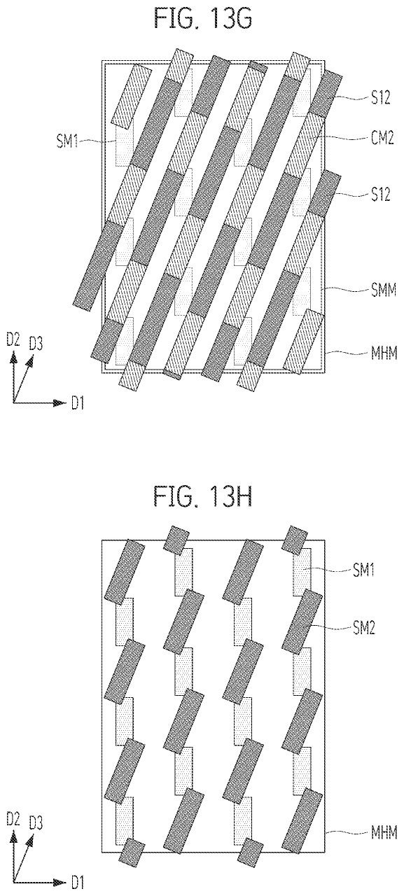

FIGS. 13A to 13I illustrate a method for forming a main hard mask layer pattern.

Referring to FIG. 13A, first partition patterns P11 may be formed over a main hard mask layer MHM. The first partition patterns P11 may include a carbon-containing material. The first partition patterns P11 may extend long in the second direction D2.

First spacer lines S11 may be formed on both sidewalls of the first partition patterns P11. The first spacer lines S11 may include silicon oxide.

Referring to FIG. 13B, the first partition patterns P11 may be removed. As a result, the first spacer lines S11 may be arranged spaced apart from each other in the first direction D1.

Referring to FIG. 13C, a plurality of first cut mask layers CM1 may be formed over the first spacer lines S11. The first cut mask layers CM1 may be disposed over the first spacer lines S11. The first cut mask layers CM1 may include a photoresist pattern.

Referring to FIG. 13D, the first spacer lines S11 may be etched using the first cut mask layers CM1 as barriers. As a result, a plurality of first sacrificial mask layers SM1 may be formed over the main hard mask layer MHM.

Referring to FIG. 13E, a middle sacrificial mask layer SMM may be formed over the first sacrificial mask layers SM1.

Second partition patterns P12 may be formed over the middle sacrificial mask layer SMM. The second partition patterns P12 may include a carbon-containing material. The second partition patterns P12 may extend long in the third direction D3.

Subsequently, second spacer lines S12 may be formed on both sidewalls of the second partition patterns P12. The second spacer lines S12 may include silicon oxide. The second spacer lines S12 may extend long in the third direction D3.

Referring to FIG. 13F, the second partition patterns P12 may be removed. As a result, the second spacer lines S12 may be arranged spaced apart from each other in the first direction.

Referring to FIG. 13G, a plurality of second cut mask layers CM2 may be formed over the second spacer lines S12. The second cut mask layers CM2 may be disposed over the second spacer lines S12. The second cut mask layers CM2 may include a photoresist pattern.

Referring to FIG. 13H, the second spacer lines S12 may be etched using the second cut mask layers CM2 as barriers. As a result, a plurality of second sacrificial mask layers SM2 may be formed over the middle sacrificial mask layer SMM.

Referring to FIG. 13I, after the second cut mask layers CM2 are removed, the main hard mask layer MHM may be formed by using the first sacrificial mask layers SM1 and the second sacrificial mask layers SM2 as barriers. As a result, a plurality of main hard mask layer patterns MHM′ may be formed. The individual main hard mask layer patterns MHM′ may include first portions HM1 corresponding to the shapes of the first sacrificial mask layers SM1, and second portions HM2 corresponding to the shapes of the second sacrificial mask layers SM2.

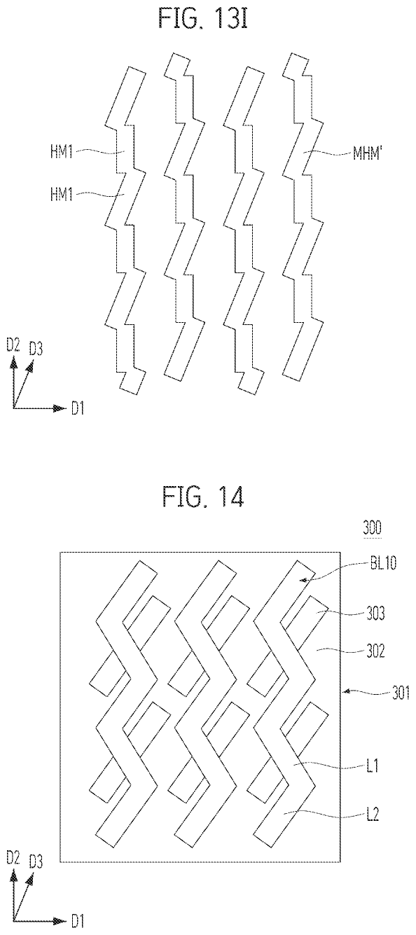

FIG. 14 illustrates a semiconductor device 300 in accordance with another embodiment of the present invention.

The semiconductor device 300 of FIG. 14 may be similar to the semiconductor device 100 of FIG. 1A.

Referring to FIG. 14, the semiconductor device 300 may include a substrate 301, a plurality of active regions 303, and an isolation layer 302. The semiconductor device 300 may further include a plurality of bit lines BL10. Each bit line BL10 may include first line portions L1 and second line portions L2. The first line portions L1 may extend in a direction that intersects with the active regions 303. The second line portions L2 may overlap with the isolation layer 302. The individual bit lines BL10 may have a zigzag shape in which the first line portions L1 and the second line portions L2 are alternately arranged. The active regions 303 may be arranged regularly and symmetrically in the first direction D1.

According to an embodiment of the present invention, the open area of a storage node contact hole may be maximized by minimizing the interference between the storage node contact plug and the bit line, thereby suppressing not-open defects that may be caused due to line width scaling and defects that may be caused due to increased resistance.

While the present invention has been described with respect to specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A method for fabricating a semiconductor device, the method comprising:
forming an isolation layer that defines a plurality of active regions over a substrate;
forming a bit line stack over the substrate;
forming a main hard mask layer over the bit line stack;
forming a plurality of first sacrificial mask layers over the main hard mask layer;
forming a plurality of second sacrificial mask layers overlapping with both side ends of the first sacrificial mask layers over the first sacrificial mask layers;
forming a main hard mask layer pattern by using the first and second sacrificial mask layers as barriers and etching the main hard mask layer; and
forming a bit line structure by using the main hard mask layer pattern as a barrier and etching the bit line stack.

2. The method of claim 1, wherein the first sacrificial mask layers extend in a first direction, and
the second sacrificial mask layers extend in a second direction that intersects with the first direction.

3. The method of claim 1, wherein the first sacrificial mask layers extend in a direction that intersects with the active regions, and
the second sacrificial mask layers are overlapping with the isolation layer.

4. The method of claim 1, wherein the main hard mask layer pattern includes:
first portions corresponding to the first sacrificial mask layers; and
second portions corresponding to the second sacrificial mask layers, and
the first portions and the second portions are disposed at the same horizontal level.

5. The method of claim 4, wherein the bit line structure includes:
first line portions corresponding to the first portions; and
second line portions corresponding to the second portions, and
the first line portions and the second line portions are disposed at the same horizontal level.

6. The method of claim 1, wherein the forming of the first sacrificial mask layers includes:
forming a first partition pattern over the main hard mask layer;
forming first spacer lines on both sidewalls of the first partition pattern;
removing the first partition pattern;
forming a first cut mask layer over the first spacer lines; and
forming the first sacrificial mask layers by using the first cut mask layer as a barrier and etching the first spacer lines.

7. The method of claim 1, wherein the forming of the second sacrificial mask layers includes:
forming a second partition pattern over the first sacrificial mask layer;
forming second spacer lines on both sidewalls of the second partition pattern;
removing the second partition pattern;
forming a second cut mask layer over the second spacer lines; and
forming the second sacrificial mask layers by using the second cut mask layer as a barrier and etching the second spacer lines.

8. The method of claim 1, further comprising:
before forming the second sacrificial mask layers,
forming a middle sacrificial hard mask layer over the first sacrificial mask layers.

9. A semiconductor device comprising:
a substrate;
an isolation layer formed over the substrate and defining a plurality of active regions;
a bit line contact plug coupled to a portion of the active regions; and
a bit line formed over the bit line contact plug,
wherein the bit line includes:
first line portions that intersect with the active regions; and
second line portions that extend in a direction different from a direction of the first line portions and overlap with the isolation layer.

10. The semiconductor device of claim 9, further comprising:
a gate trench formed in the active region; and
a buried word line formed in the gate trench.

11. The semiconductor device of claim 9, further comprising:
spacer structures formed on both sidewalls of the bit line.

12. The semiconductor device of claim 9, wherein both sidewalls of the bit line have non-linearity in a direction that the bit line extends.

13. The semiconductor device of claim 9, wherein the first line portions and the second line portions are alternately arranged in a direction that the bit line extends.

14. The semiconductor device of claim 9, wherein the first line portions and the second line portions include a same material.

15. The semiconductor device of claim 9, wherein the first line portions and the second line portions have a same width and length.

16. The semiconductor device of claim 9, further comprising:
a bit line contact plug disposed below the bit line; and
a bit line hard mask over the bit line contact plug,
wherein the bit line hard mask has a same shape as a shape of the bit line.

17. The semiconductor device of claim 9, wherein the bit line includes a zigzag shape in which the first line portions and the second line portions are alternately arranged.

18. The semiconductor device of claim 9, further comprising:
storage node contact plugs neighboring the second line portions,
wherein the storage node contact plugs are coupled to edges of the active regions.

19. The semiconductor device of claim 9, wherein the second line portions and the active regions have non-overlapping directions.

20. A semiconductor device comprising:
a plurality of active regions separated by an isolation layer; and
a bit line stacked structure coupled to at least portions of the active regions;
wherein the bit line stacked structure comprises a non-linear bit line which includes a plurality of alternating first and second line segments, and
wherein the first and second line segments extend in a first and a second direction respectively.
